(19) United States
(12) Patent Application Publication
(10) Pub. No.: US 2015/0351271 A1
(43) Pub. Date: Dec. 3, 2015

(54) HANDHELD ELECTRONIC DEVICE CARRYING CASE

(71) Applicant: Sheniqua Dawson, Deltona, FL (US)

(72) Inventor: Sheniqua Dawson, Deltona, FL (US)

(21) Appl. No.: 14/291,215

(22) Filed: May 30, 2014

(51) Int. Cl. H05K 5/03; H05K 5/02; B65D 51/28; H05K 5/00

(52) U.S. Cl. CPC H05K 5/03; H05K 5/0086; H05K 5/0226; H05K 5/0234; B65D 51/28

(57) ABSTRACT

A carrying case for an electronic device comprising a housing, where the housing includes an inner cavity with a peripheral edge to receive the electronic device; a lid attached to the housing, where the lid covers a screen of the electronic device; and a storage compartment on an inner surface of the lid, where the storage compartment includes a plurality of pockets to receive a plurality of accessories for the electronic device. The plurality of pockets enable storage of a charger and additional power source to ensure the user is never without power.

### BACKGROUND OF THE INVENTION

1. Field of the Invention

The present invention relates to a case for a handheld electronic device, where the case includes storage compartments for a charger.

2. Description of Related Art

Handheld electronic devices are popular work, entertainment and design tools, enjoyed by many because of their simplicity of use and wide user appeal. Young and old are able to use the devices like smartphones, computer tablets, digital music players and the like because they are strategically designed to be intuitive and user friendly allowing almost anyone to use them. Smartphones are especially convenient in combining the utility of a telephone with the powerful processing of a computer, image capture and resolution of a camera, and quality sound output of a music player.

While these tools are fun and helpful, they are also very delicate and require continuous monitoring of the battery life to ensure the device is charged. Typically a cover or case is placed over the smartphone or tablet to prevent scratching and damage to the external surfaces. This is especially important for the touchscreen, because all the navigating is done by touching the screen. A problem with the case is that they do not offer any additional storage for the electronic device. Often, while away from home, the user will need to recharge their smartphone to continue use. They must either prepare in advance to keep their charger in another storage device or borrow a charger from another user, because a charger does not fit in a standard case. If neither option is available, the smartphone runs out of charge and the person must wait until they are home to power the device again.

Therefore it would be beneficial in the art to provide a smartphone or tablet holder that includes additional storage for a charger. It would also be desirable in the art to provide a smartphone holder that includes a way to protect the screen and prevent damage during use.

### SUMMARY OF THE INVENTION

In view of the foregoing disadvantages inherent in the prior art, the general purpose of the present invention is to provide a carrying case for an electronic device, configured to include all of the advantages of the prior art, and to overcome the drawbacks inherent therein.

Accordingly, an object of the present invention is to provide a carrying case for a handheld electronic device that includes a storage compartment to store a charger and an additional power source.

To achieve the above objects, in an aspect of the present invention, a carrying case for an electronic device is described comprising a housing, where the housing includes an inner cavity with a peripheral edge to receive the electronic device; a lid attached to the housing, where the lid covers a screen of the electronic device; and a storage compartment on an inner surface of the lid, where the storage compartment includes a plurality of pockets to receive a plurality of accessories for the electronic device. The plurality of pockets enable storage of a charger and additional power source to ensure the user is never without power.

These together with other aspects of the present invention, along with the various features of novelty that characterize the present invention, are pointed out with particularity in the claims annexed hereto and form a part of this present invention. For a better understanding of the present invention, its operating advantages, and the specific objects attained by its uses, reference should be made to the accompanying drawings and descriptive matter in which there are illustrated exemplary embodiments of the present invention.

### BRIEF DESCRIPTION OF THE DRAWINGS

The advantages and features of the present invention will become better understood with reference to the following detailed description and claims taken in conjunction with the accompanying drawings, wherein like elements are identified with like symbols, and in which:

FIG. 1 depicts a perspective view of a handheld electronic device carrying case in accordance with an exemplary embodiment of the present invention; and

FIG. 2 depicts a backside view of a handheld electronic device carrying case in accordance with an exemplary embodiment of the present invention.

Like reference numerals refer to like parts throughout the description of several views of the drawings.

### DETAILED DESCRIPTION OF THE DRAWINGS

The present invention relates to a case for a handheld electronic device, where the case includes storage compartments for a charger. The present invention provides a handheld electronic device carrying case to allow users to store their charger cord within the case of their electronic device. The carrying case includes multiple pockets within the lid for the user to place the accessories associated with the electronic device. With the handheld electronic device carrying case the user is afforded a product that incudes access to a power source as well as the opportunity to store additional items all within a convenient storage compartment.

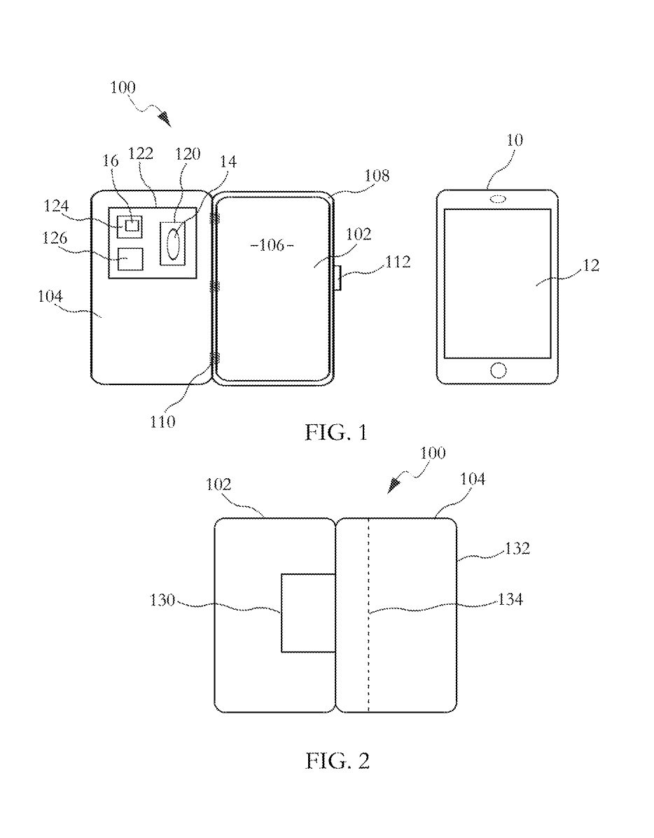

Turning now descriptively to the drawings, referring to FIG. 1, a handheld electronic device carrying case 100 is shown in accordance with an exemplary embodiment of the present invention. The carrying case 100 includes a housing 102 to receive an electronic device 10. The electronic device 10 may be a smartphone like an iPhone, Droid, Galaxy, or Lumia, a tablet computer like an iPad, or Surface, or an electronic reader like a Kindle. The list of electronic devices is merely exemplary and not to be considered an exhaustive list. The housing 102 includes in inner cavity 106 to receive the electronic device 10, and further a rim 108 to secure the electronic device 10 within the inner cavity 106. The inner cavity 106 may be covered with a felt material or rubber to prevent scratching on the surface of the electronic device 10 during storage.

Along an edge of the housing 102 a lid 104 is attached on a hinge 110. The hinge 110 enables the lid 104 to easily open and close while being in continuous contact with the housing 102. The lid 104 is covered in a soft felt material to prevent scratches on the screen 12 of the electronic device 10. The housing 102 and the lid 104 may be made from a variety of different materials including rubber, leather, plastic, vinyl, neoprene or the like. To secure the lid 104 against the housing 102 the carrying case 100 includes a closure 112. The closure 112 may be a snap, magnet, zipper, hook and loop fastener or the like.

On the inner surface of the lid 104 is a storage compartment 120. The storage compartment 120 includes a plurality of pockets 122, 124, 126 to receive a plurality of accessories associated with the electronic device 10. A first pocket 122 may be used as a charger pocket to store a charger 14 for the electronic device 10. A second pocket 124 may be used to store an additional battery or power source 16 for the electronic device 10. Finally, a third pocket 126 may store any additional items like a cloth, stylus, headphones, light or the like. The exterior surface of the pockets 122, 124, 126 is covered with the same soft felt as the lid 104 to ensure no scratching on the screen 12. With the plurality of pockets 122, 124, 126 the user is able to store all of their accessories to ensure that they are never without power and that the carrying case 100 is an all-in-one storage location for their electronic device 10. While the electronic device 10 rests within the housing 102, the inner cavity 106 is deep enough to ensure that the plurality of pockets 122, 124, 126 do not interfere with the screen 12 of the electronic device 10 when the lid 104 is over the housing 102. Therefore, the storage compartment 120 rests flush or just above the screen 12 when the carrying case 100 is closed.

Referring now to FIG. 2 a backside view of the handheld electronic device carrying case 100 is shown in accordance with an exemplary embodiment of the present invention. The backside of the housing 102 may include a stand 130. The stand 130 may be propped up alone or may receive an outer edge 132 of the lid 104. To enable the housing 102 to stand upright while using the electronic device 10, the stand 130 may extend from the housing 102 at an angle to elevate the back side of the housing 102. Alternatively, the lid 104 may fold along a seam 134 to allow the edge 132 to insert into the stand 130. This way the carrying case 100 serves as not only a storage device but also an elevator upon which the user may prop their electronic device 10.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The exemplary embodiment was chosen and described in order to best explain the principles of the invention and its practical application, to thereby enable others skilled in the art to best utilize the invention and various embodiments with various modifications as are suited to the particular use contemplated.

What is claimed is:

1. A carrying case for an electronic device comprising:
a. a housing, where the housing includes an inner cavity with a peripheral edge to receive the electronic device;
b. a lid attached to the housing, where the lid covers a screen of the electronic device; and
c. a storage compartment on an inner surface of the lid, where the storage compartment includes a plurality of pockets to receive a plurality of accessories for the electronic device.

2. The carrying case according to claim 1, where the housing and the lid are fastened together with a hinge.

3. The carrying case according to claim 1, where the plurality of pockets includes at least two pockets, a charger pocket and an additional power source pocket.

4. The carrying case according to claim 1, where the housing includes a stand on a backside, where the stand props up housing to use the electronic device.

5. The carrying case according to claim 4, where the stand receives an outer edge of the lid, where the lid folds at a seam to insert the outer edge into the stand.

6. The carrying case according to claim 1, where the housing is secured against the lid with a closure.

7. The carrying case according to claim 6, where the closure is one of at least a snap, zipper, hook and loop fastener, or magnet.

8. The carrying case according to claim 1, where the lid and the storage compartment are covered in a soft felt material to prevent scratching the screen of the electronic device.

9. The carrying case according to claim 1, where the inner cavity of the housing is deep enough to receive the electronic device and the plurality of pockets, where the storage compartment rests flush against the screen when the carrying case is closed.
